(19) United States
(12) Patent Application Publication
(10) Pub. No.: US 2021/0036215 A1
(43) Pub. Date: Feb. 4, 2021

(54) METHOD FOR POLING PIEZOELECTRIC ACTUATOR ELEMENTS

(71) Applicant: XAAR TECHNOLOGY LIMITED, Cambridge (GB)

(72) Inventors: Charalampos FRAGKIADAKIS, Cambridge (GB); Peter MARDILOVICH, Cambridge (GB); Susan TROLIER-MCKINSTRY, University Park, PA (US)

(73) Assignee: XAAR TECHNOLOGY LIMITED, Cambridge (GB)

(21) Appl. No.: 16/967,373

(22) PCT Filed: Jan. 31, 2019
(86) PCT No.: PCT/GB2019/050267

§ 371 Date: Aug. 4, 2020

(30) Foreign Application Priority Data
Feb. 5, 2018 (GB) 1801830.9

(51) Int. Cl. H01L 41/257; B41J 2/16; H01L 41/09

(52) U.S. Cl. CPC H01L 41/257; B41J 2/1607; H01L 41/0973; B41J 2/1642

(57) ABSTRACT

A method of poling piezoelectric elements of an actuator comprises applying an electric pulse heating waveform to the piezoelectric element(s) in order to increase the temperature thereof to a poling temperature (S202), applying an electric field poling waveform to the piezoelectric element(s) for a poling time period (S203), and apply an electric field holding poling waveform to the piezoelectric element(s) to maintain poling whilst the temperature of the actuator decreases (S204).

### FIELD OF THE INVENTION

The present invention relates to a method for poling piezoelectric elements. It may find particularly beneficial application poling piezoelectric elements of piezoelectric actuators for use in a droplet deposition head such as a printhead.

### BACKGROUND

It is known that poling the piezoelectric elements of piezoelectric actuators can improve the performance and reliability of the actuators. However, over time and with use the polarisation can reduce.

Corona discharge poling is a method of poling the piezoelectric elements of piezoelectric actuators at die level or wafer level. The Corona discharge method requires the bare actuator to be situated between the electrodes of the corona discharge device.

Another method of poling the piezoelectric elements of piezoelectric actuators is the Heat and DC field method, which involves the application of an external DC field to the piezoelectric elements, at elevated temperature, then cooling the piezoelectric elements whilst maintaining the external field. This method requires heating apparatus as well as apparatus for applying the external field. A further method of poling the piezoelectric elements of piezoelectric actuators involves the application of a poling DC field to the piezoelectric elements, at room temperature, but this method does not always produce an adequately stable polarization state.

Both methods require a dedicated set up. In addition, the above methods cannot be performed once a droplet deposition head has been assembled to restore performance of the droplet deposition head.

### BRIEF DESCRIPTION OF THE DRAWINGS

Embodiments will now be described with reference to the accompanying figures of which:

FIG. 1 illustrates schematically a cross-section view of a portion of an actuator die of an inkjet piezoelectric printhead;

FIGS. 2(i), 2(ii) and 2(iii) illustrate schematically the dipoles of a piezoelectric element;

FIG. 3 illustrates a graph of a poling process of a piezoelectric element;

FIGS. 4A and 4B illustrate schematically the poling of piezoelectric elements of a plurality of actuators at a die level;

FIG. 5A illustrates an example of a waveform that can be used for heating and/or poling piezoelectric elements;

FIG. 5B illustrates an example of a waveform that can be used for heating and/or poling piezoelectric elements;

FIG. 6 illustrates a flow diagram of a process for poling the piezoelectric elements of a plurality of piezoelectric actuators;

FIG. 7 illustrates a flow diagram of another process for poling the piezoelectric elements of a plurality of piezoelectric actuators;

FIGS. 8A, 8B and 8C illustrate schematically poling and heating waveforms for maintaining temperature whilst poling; and

FIG. 9 illustrates a controller.

### DETAILED DESCRIPTION

A method of poling the piezoelectric elements of a plurality of actuators comprises applying an electric pulse (heating waveform) to a plurality of piezoelectric elements in order to increase the temperature of the piezoelectric elements to a poling temperature. A poling electric field (poling waveform) is then applied to one or more of the plurality of piezoelectric elements for a poling time period to pole the piezoelectric elements. A holding poling electric field (holding poling waveform) is then applied to the one or more of the plurality of piezoelectric elements to maintain poling whilst the temperature of the actuator decreases.

The following disclosure describes a method for poling piezoelectric elements of a plurality of piezoelectric actuators. The method comprises: applying a heating waveform to one or more of the piezoelectric elements to increase the temperature of the plurality of piezoelectric actuators from a first temperature to a poling temperature; applying a poling waveform to one or more of the piezoelectric elements when the poling temperature has been reached, for a poling time period, to pole the one or more piezoelectric elements; and after expiry of the poling time period, applying a holding poling waveform to the one or more piezoelectric elements to which the poling waveform was applied until the temperature of the plurality of piezoelectric actuators has decreased from the poling temperature to a second temperature.

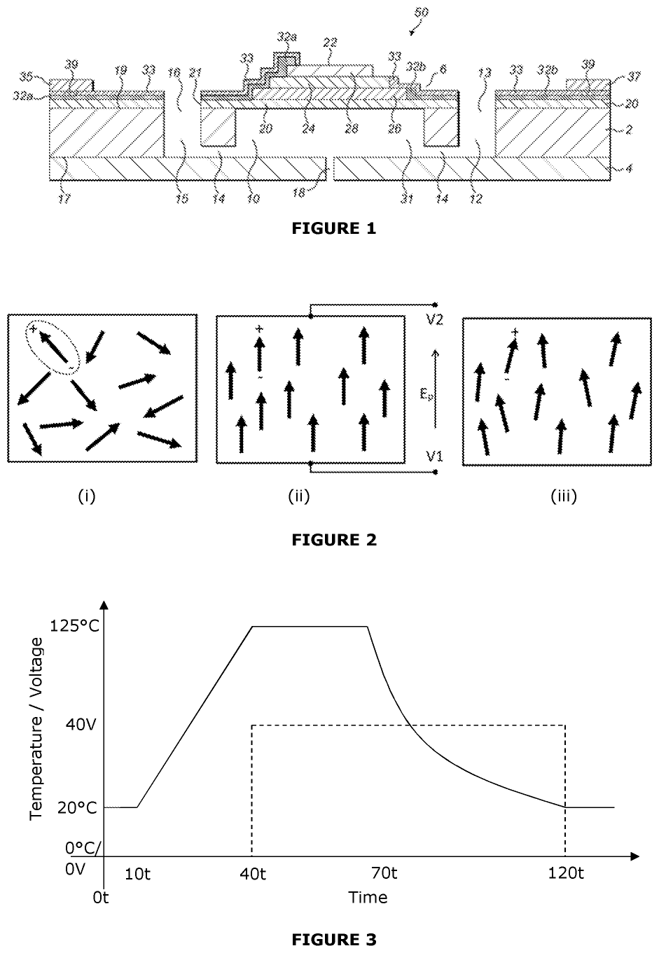

FIG. 1 is a schematic diagram showing a cross-section view of a portion of an actuator die 50 of an inkjet piezoelectric printhead having a known circuit configuration.

In the following description, the inkjet printhead is described as a thin film inkjet piezoelectric printhead, which has a thin film piezoelectric element in each actuator and may be fabricated using any suitable fabrication process(es) or technique(s), such as those used to fabricate structures for CMOS and/or MEMS.

The inkjet printhead is not limited to being a thin film inkjet printhead, nor is the inkjet printhead limited to being fabricated using such processing techniques as described above. Instead, any other suitable fabrication process(es) may be used, such as, for example, machining a bulk piezoelectric actuator with a dicing saw and bonding it to the fluidic chamber.

The die 50 comprises a fluidic chamber substrate 2 and a nozzle layer 4.

The die 50 comprises a droplet generating unit 6, hereinafter “droplet unit”. The die 50 may comprise a plurality of droplet units 6 arranged in arrays thereon as will be described below.

As shown in FIG. 1, the droplet unit 6 comprises a fluidic chamber 10 and a fluidic inlet port 13 in fluidic communication therewith via a fluidic supply channel 12. The fluidic inlet port 13 is provided at a top surface 19 of the fluidic chamber substrate 2 towards one end of the fluidic chamber 10 along a length thereof.

In the present embodiment, fluid, hereinafter “ink”, is supplied to the fluidic chamber 10 from the fluidic inlet port 13. Although the following description refers to the fluid being “ink”, any pigmented fluid, or non-pigmented fluid, such as a functional fluid, may be used. The droplet unit 6 further comprises a fluidic channel 14 provided within the fluidic chamber substrate 2 in fluidic communication with the fluidic supply channel 12 and fluidic chamber 10, and arranged to provide a path for ink to flow there between.

The droplet unit 6 also comprises a fluidic outlet port 16 in fluidic communication with the fluidic chamber 10, whereby ink may flow from the fluidic chamber 10 to the fluidic outlet port 16 via a fluidic channel 14 and fluidic return channel 15 formed in the fluidic chamber substrate 2.

The fluidic outlet port 16 is provided at the top surface 19 of the fluidic chamber substrate 2 towards an end of the fluidic chamber 10 opposite the end from which the fluidic inlet port 13 is provided.

Alternatively, the fluidic inlet port 13 and/or fluidic outlet port 16 may be provided within the fluidic chamber 10.

Alternatively, ink may be supplied and/or returned via port(s) provided at the side(s) of the die.

An inkjet printhead comprising droplet units 6 having fluidic inlet ports 13 and fluidic outlet ports 16, whereby ink flows continuously from the fluidic inlet port 13 to the fluidic outlet port 16, along the length of the fluidic chamber 10 may be considered to operate in a recirculation mode, hereinafter “through-flow” mode.

In alternative embodiments, ink may be supplied to the fluidic chamber 10 from both fluidic ports 13 and 16 or whereby the die 50 is not provided with a fluidic outlet port 16 and/or fluidic return channel 15 such that substantially all of the ink supplied to the fluidic chamber 10 is ejected from the nozzle 18, whereby the inkjet printhead may be considered to operate in a non through-flow mode.

The fluidic chamber substrate 2 may comprise silicon (Si), and may, for example, be manufactured from a Silicon (Si) wafer, whilst the associated features, such as the fluidic chamber 10, fluidic channels 12/15, fluidic inlet/outlet ports 13/16 and fluidic channels 14 may be formed using any suitable fabrication process, e.g. an etching process, such as deep reactive ion etching (DRIE) or chemical etching.

Additionally or alternatively, the associated features of the fluidic chamber substrate 2 may be formed from an additive process e.g. a chemical vapour deposition (CVD) technique (for example, plasma enhanced CVD (PECVD)), atomic layer deposition (ALD), or the features may be formed using a combination of removal and/or additive processes.

In the present example, the nozzle layer 4 is provided at a bottom surface 17 of the fluidic chamber substrate 2, whereby “bottom” is taken to be a side of the fluidic chamber substrate 2 having the nozzle layer 4 thereon. It will be appreciated that the nozzle layer may be provided on a different surface other than the bottom surface.

The surfaces of various features of the die 50 may be coated with protective or functional materials, such as, for example, a suitable coating of passivation material or wetting material.

The droplet unit 6 further comprises a nozzle 18 in fluidic communication with the fluidic chamber 10, whereby the nozzle 18 is formed in the nozzle layer 4 using any suitable process e.g. chemical etching, deep reactive-ion etching (DRIE), laser ablation etc.

The droplet unit 6 further comprises a vibration plate 20, provided at the top surface 19 of the fluidic chamber substrate 2, and arranged to cover the fluidic chamber 10. The top surface 19 of the fluidic chamber substrate 2 is taken to be the surface of the fluidic chamber substrate 2 opposite the bottom surface 17.

The vibration plate 20 is deformable to generate pressure fluctuations in the fluidic chamber 10, so as to change the volume within the fluidic chamber 10, such that ink may be ejected from the fluidic chamber 10 via the nozzle 18, e.g. as a droplet, and/or for drawing ink into the fluidic chamber e.g. via the fluidic inlet port 13.

The vibration plate 20 may comprise any suitable material, such as, for example a metal, an alloy, a dielectric material and/or a semiconductor material. Examples of suitable materials include silicon nitride (Si3N4), silicon dioxide (SiO2), aluminium oxide (Al2O3), titanium dioxide (TiO2), silicon (Si) or silicon carbide (SiC). The vibration plate 20 may additionally or alternatively comprise multiple layers.

The vibration plate 20 may be formed using any suitable processing technique, such as, for example, ALD, sputtering, electrochemical processes and/or a CVD technique. When the vibration plate 20 is provided on the top surface 19, apertures 21 corresponding to the fluidic ports 13/16 may be provided in the vibration plate 20, e.g. using a suitable patterning technique for example during the formation of the vibration plate 20.

The droplet unit 6 further comprises an actuator 22 provided on the vibration plate 20, which is arranged to deform the vibration plate 20.

However, any suitable type of actuator or electrode configuration capable of effecting droplet generation may be used, for example, the actuator may act upon a membrane that is in fluidic communication with the nozzle chamber without being directly opposite or in direct communication with the nozzle chamber.

The actuator 22 is depicted as a piezoelectric actuator 22 comprising a piezoelectric element 24 provided with two electrodes 26 and 28. The piezoelectric element 24 may comprise any piezoelectric material, such as lead zirconate titanate (PZT).

An electrode is provided in the form of a lower electrode on the vibration plate 20. The piezoelectric element 24 is provided on the lower electrode 26 using any suitable deposition technique. The piezoelectric element 24 may be formed by chemical solution deposition (CSD). For example, a sol-gel deposition technique may be used to deposit successive layers of piezoelectric material to form the piezoelectric element 24 on the lower electrode 26.

A further electrode in the form of an upper electrode 28 is provided on the piezoelectric element 24 at the opposite side of the piezoelectric element 24 to the lower electrode 26, however any suitable configuration of the electrodes could be used.

The electrodes 26/28 may comprise any suitable material e.g. iridium (Ir), ruthenium (Ru), platinum (Pt), nickel (Ni) iridium oxide (Ir₂O₃), Ir₂O₃/Ir and/or gold (Au). The electrodes 26/28 may be formed using any suitable technique, such as a sputtering technique.

The electrodes 26/28 and the piezoelectric element 24 may be patterned separately or in the same processing step to define the actuator 22.

When a voltage differential is applied between the electrodes 26/28, stress and strain are generated in the piezoelectric element 24, causing the piezoelectric actuator 22 to deform on the vibration plate 20. This deformation changes the volume within the fluidic chamber 10 and ink droplets may be discharged from the nozzle 18 by driving the piezoelectric actuator 22 with an appropriate signal. The signal may be supplied from a controller (not shown), for example, as a voltage waveform. The controller may comprise a power amplifier or switching circuit connected to a computer running an application which generates signals in response to print data provided thereto e.g. uploaded thereto by a user.

Further material/layers (not shown) may also be provided in addition to the electrodes 26/28 and piezoelectric elements 24 as required.

A wiring layer comprising electrical connections is provided on the vibration plate 20, whereby the wiring layer may comprise two or more electrical traces 32a/32b for example, to connect the upper electrode 28 and/or lower electrode 26 to the controller, directly or via further drive circuitry. The electrical traces 32a/32b may form part of the piezoelectric actuator 22.

FIG. 1 schematically illustrates the electrical trace 32a and the first electrode 28 are in electrical communication with a first electrical connection 35 in the form of an electrical contact (e.g. a drive contact), whilst the electrical trace 32b and the second electrode 26 are in electrical communication with a second electrical connection in the form of an electrical contact 37 (e.g. a ground contact). The electrical contacts 35/37 are, in turn, in electrical communication with the controller (not shown).

Using such a configuration, signals (e.g. a voltage waveform) can be supplied to the piezoelectric element of the actuator 22 from the controller for controlled driving thereof.

The electrical traces 32a/32b comprise a conductive material, e.g. copper (Cu), gold (Ag), platinum (Pt), iridium (Ir), aluminium (Al), titanium nitride (TiN).

The wiring layer may comprise further materials (not shown), for example, a passivation material 33 to protect the electrical traces 32a/32b e.g. from the environment and from contacting the ink.

Additionally or alternatively, the passivation material 33 may comprise a dielectric material provided to electrically insulate electrical traces 32a/32b from each other e.g. when stacked atop one another or provided adjacent each other. The passivation material may comprise any suitable material, for example: silicon dioxide (SiO₂), aluminium oxide (Al₂O₃) or silicon nitride (Si₃N₄).

FIG. 1 is a schematic diagram, and the electrical contacts 35/37 may be deposited on the actuator die 50 using any suitable technique and in any suitable configuration. The electrical contacts 35/37 may be formed of a conductive material e.g. copper (Cu), gold (Au), platinum (Pt), aluminium (Al) etc.

Furthermore, the electrical contacts 35/37 may be deposited atop the passivation material 33, whereby electrical vias 39 provide electrical communication between the electrical contacts 35/37 and the electrical traces 32a/32b. Alternatively, the contacts 35/37 may, for example, be provided directly atop the electrical traces 32a/32b. Although not explicitly described, further materials may be provided within the wiring layer to prevent unwanted electrical contact between the electrical traces 32a/32b and other materials as required.

The actuator die 50 may comprise a plurality of droplet units 6, for example separated by partition walls 31 provided between each of the droplet units 6 along the length direction of the fluidic chamber substrate 2.

Turning now in more detail to the piezoelectric element 24, FIGS. 2(i), 2(ii) and 2(iii) are schematic diagrams illustrating the dipoles (represented as arrows) in the piezoelectric element. As illustrated in FIG. 2(i), there is no pronounced spontaneous dipole polarisation of the piezoelectric element, such that most of the dipoles of the piezoelectric element are randomly oriented. In FIG. 2(i), the dipoles (arrows) are in a random distribution of orientation. In order to create an initial alignment state in the piezoelectric element such that most of the dipoles are oriented in substantially the same dipole direction, the piezoelectric element is poled.

In order to pole the piezoelectric element, the temperature of the piezoelectric element is increased to a poling temperature and then held at the poling temperature whilst a poling electric field Eₚ, having a predetermined field strength, is applied across the piezoelectric element, from a first electrode V₁ to a second electrode V₂. The poling electric field Eₚ exceeds the coercive field E_{c} of the material of the piezoelectric element. During application of the poling electric field Eₚ, the dipoles of the piezoelectric element align along the direction of the poling electric field Eₚ. The poling electric field Eₚ is applied for a predetermined period of time (a poling time period) whilst the piezoelectric element is held at the poling temperature. FIG. 2(ii) illustrates the dipoles of the piezoelectric element being aligned along the direction of the poling electric field Eₚ, whilst the poling electric field Eₚ is being applied.

After the poling time period has elapsed, the piezoelectric element is cooled down from the poling temperature to a second temperature, for example, room temperature, whilst an electric field Eₚ₁ also exceeding E_{c}, is maintained. The electric field Eₚ₁ is maintained during at least a portion of the cooling process, and preferably throughout the entire cooling process until the second temperature has been reached, to prevent the piezoelectric element from depoling whilst being at a higher temperature. Once the piezoelectric element has cooled down, the electric field Eₚ₁ is removed. As illustrated in FIG. 2(iii), following poling and removal of the electric field Eₚ₁, the dipoles of the piezoelectric element relax slightly but still point along a net dipole orientation that is aligned to the previous poling electric field Eₚ direction, giving rise to a remanent polarization of the piezoelectric element after poling (illustrated in FIG. 2(iii)) that exceeds the level of remanent polarisation before poling (illustrated in FIG. 2(i)). The electric field Eₚ₁ may have the same electric field strength as the poling electric field Eₚ, or may have a different electric field strength from the poling electric field Eₚ.

FIG. 3 shows a graph of temperature versus time illustrating a known poling process of a piezoelectric element. In FIG. 3, the solid line represents the temperature of the piezoelectric element and the dotted line represents the voltage applied to the piezoelectric element. The piezoelectric element is initially at 20° C. (a first temperature), and no poling electric field Eₚ is applied (here shown as 0V, although it could be any field smaller than the coercive field E_{c}). From time 10t, the temperature of the piezoelectric element is increased until a time 40t, for example by use of a hot plate or an oven etc. At time 40t, the temperature of the piezoelectric element has reached a predetermined poling temperature, which in FIG. 3 is 125° C., although the poling temperature is not limited to being 125° C. In addition, at time 40t a poling electric field Eₚ (40V) is applied to the piezoelectric element, as represented by the dotted line. The poling electric field Eₚ and the poling temperature are maintained for the poling time period, which in FIG. 3 is from time 40t to 70t. From time 70t, the piezoelectric element is cooled down from the poling temperature, for example by turning off the hot plate or oven, or by removing the piezoelectric element from the heat source. The poling electric field Eₚ is maintained until the piezoelectric element has cooled down to a second temperature. According to FIG. 3, the piezoelectric element has cooled down to 20° C. (the second temperature) at time 120t. When the piezoelectric element has cooled down to the second temperature, the poling electric field Eₚ is removed (0V).

As stated above, following poling, the dipoles of the piezoelectric element have a remanent polarization that exceeds the level of remanent polarisation before poling.

The field strength of the poling electric field, the poling temperature and the poling time period may all be varied. For example, in order to achieve a similar poling effect, a lower poling electric field may be applied when a higher poling temperature and/or longer poling time period is applied; a lower poling temperature may be applied when a higher poling electric field and/or a longer poling time period is applied; or a shorter poling time period may be applied when a higher poling electric field and/or a higher poling temperature is applied.

Conventionally, in the case of thin film piezoelectric actuators, the piezoelectric element may be poled at wafer level prior to forming a cavity below the membrane supporting the piezoelectric element; or at die level, after forming a cavity below the membrane supporting the piezoelectric element.

When poling at wafer level, before the cavity formation (“clamped” configuration), the membrane 20 that the piezoelectric actuator 22 is supported on is not able to deform when a poling electric field is applied across the piezoelectric element 24 of the piezoelectric actuator 22 and thus the poling process may not be fully efficient when compared to poling at die level, after the cavity formation (“partially released” configuration). However, when poling at wafer level in clamped configuration, the poling process may be less restricted with regards to the predetermined temperature or with regards to poling electric field strength compared to a full inkjet printhead assembly, since fewer materials and adhesives may be present in the pre-assembled component, and such materials or adhesives may be susceptible to degradation at elevated temperatures.

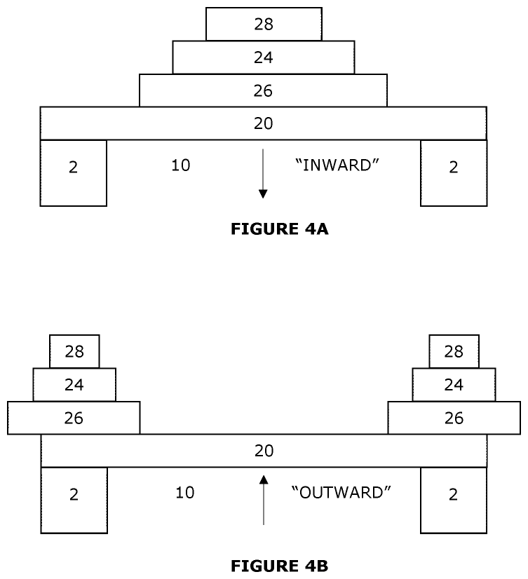

When poling at die level in the partially released configuration, the wafer 2, which supports the piezoelectric actuator 22, has been patterned to form cavities, such as the fluidic chamber 10. Consequently, the membrane 20 that supports the piezoelectric actuator 22 is able to deform when a poling electric field is applied across the piezoelectric element 24 of the piezoelectric actuator 22. It has been found that the efficiency of the poling process is improved when the membrane 20 is allowed to deform during poling. The membrane 20 may deform “inward” of the chamber 10, for example when the piezoelectric material 24 is provided above the chamber 10 and covers most of the membrane 20 area as illustrated in FIG. 4A; or the membrane 20 may deform “outward” of the chamber 10, when the piezoelectric material 24 is, for example, provided above the periphery of the chamber 10 and walls 2 and not above the central region of the chamber 10, as illustrated in FIG. 4B. Allowing the piezoelectric element to deform “inward” or “outward” during poling results in increased poling efficiency.

Conventionally, in order to pole the piezoelectric element 24 at either wafer level or die level, external heating apparatus is required, such as a hot plate or an oven in order to heat the piezoelectric element. In addition, circuitry for applying the poling electric field to the piezoelectric element is required.

The above cases relate to the manufacture stages of an inkjet printhead. Once assembled and in use, over time the remanent polarisation of the dipoles of the piezoelectric element 24 may reduce, which reduces the efficiency and lifetime of the actuator 22. It is not currently possible to pole the piezoelectric element 24 once it has been assembled into an inkjet printhead, since external heating apparatus would necessitate heating of the entire printhead and may easily damage some of its components, including any ink inside the printhead, and/or cause undesirably long down-time of the printhead due to having to heat and maintain a significant component mass at a specific temperature.

This application describes a method for poling a piezoelectric element. The method may be applied using existing drive circuitry, without the need for an external heating apparatus. Instead, the heating occurs as a result of energy losses deriving from the polarisation of the piezoelectric elements and/or resistive losses from electrodes and/or traces when current is applied. Furthermore, the thickness and/or the materials of the traces and electrodes, which characterise the electrical conductivity of the traces and electrodes may be selected in order to optimise the heating which occurs. The resulting method is quick, efficient and easy to apply.

As stated above, conventional poling processes require external heating apparatus, such as a hot plate or an oven, to heat the piezoelectric element during poling. The application of heat in combination with a poling electric field increases the efficiency of the process. It has now been discovered that a modified form of the electric signal (waveform) conventionally applied to the piezoelectric elements of the actuators 22 in order to eject droplets may be used to enable an efficient poling process. The drive circuitry is capable of applying both waveforms that are suitable for heating and for poling the piezoelectric elements.

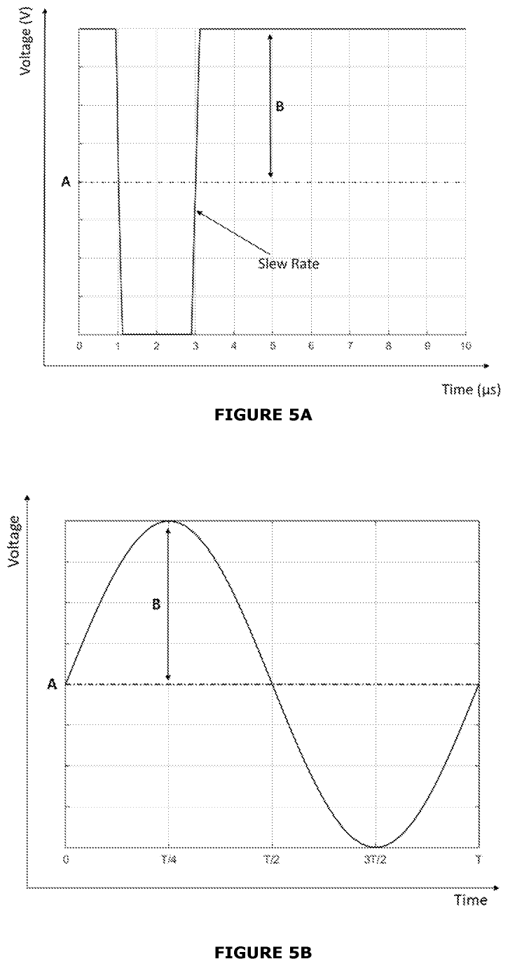

FIGS. 5A and 5B show two examples of time-varying voltage waveforms. The person skilled in the art will appreciate that any type of waveform (sinusoidal, triangle, square, trapezoidal, etc.) may be suitable.

Any waveform can be represented by the following equation (1):

V(t)=A+BW(t,f,SR) (1)

Where:

V is voltage;

W is the type of waveform (i.e. sine, trapezoidal, square etc.);

t is the time;

f=1/T is the frequency of the time varying voltage waveform, and T is the period of one cycle of the waveform;

SR is the slew rate;

A is the DC component of the time varying voltage waveform; and

B is the AC component of the time varying voltage waveform.

More generally, a waveform can be represented by the following equation (2):

V(t)=f(t,f,A,B,SR) (2)

V being a function of the parameters t, f, A, B, SR.

The person skilled in the art will appreciate that the coefficient W may include further components besides SR, especially in cases where the waveform is asymmetric in the time domain.

A, the DC component of the time varying voltage waveform, may be either positive or negative, depending on the direction of the electric field applied.

Given the above formula, the method described herein makes use of and defines a “heating waveform” as a time-varying voltage waveform of any type, frequency, DC component, AC component and slew rate, that satisfies |B|>0 and f>0.

Given the above formula, the method described herein, makes use of and defines a “poling waveform” as a time-varying voltage waveform of any type, frequency, DC component, AC component and slew rate, that satisfies |E_{c}|<|A|≤10|E_{c}|.

In one embodiment, actuators are heated and their piezoelectric elements are poled by applying in sequence at least a heating waveform, as described above, and at least a poling waveform designed to satisfy B=0, f=0, |E_{c}|<|A|≤10|E_{c}| (DC component only) to the piezoelectric elements. In another embodiment heating and poling are carried out simultaneously by applying to the piezoelectric elements at least a poling and heating waveform designed to satisfy |B|>0, f>0, |E_{c}|<|A|≤10|E_{c}| (DC and AC components). In the poling process herein described, actuators 22 may first be heated by a heating waveform. This becomes possible once the piezoelectric elements 24 are addressable by circuitry, such as during manufacture (at wafer, die or part assembly level, as long as electrodes and preferably traces and contact pads are present) or after being fully assembled and/or installed in a printer. Such a heating waveform may be used to precede the application of a poling waveform (or a recovery poling waveform, in the case of an installed printhead that has undergone a decrease in performance upon use, and discussed in detail below). The poling waveform is applied by preferably using the same circuitry used for applying the heating waveform. More preferably still, the poling and heating waveforms are applied using the same circuitry that is used for effecting droplet ejection from the nozzles. The heating waveform can be optimised for the required conditions by tuning any of A, B, f, SR, or a combination thereof. According to one embodiment, the heating waveform comprises an oscillating component, B, and is, for example a bipolar oscillating waveform. The heating waveform may further comprise a DC component, A, for example offsetting the waveform in voltage to make it unipolar. The heating waveform can have a combination of oscillating and DC components, for example, it may be a unipolar waveform with a positive or negative offset with respect to 0V.

According to another embodiment, the heating waveform comprises a frequency lower than or equal to 100 kHz. According to another embodiment, the heating waveform comprises a frequency of up to 500 kHz, and in yet another embodiment, the heating waveform comprises a frequency higher than 500 kHz, but lower than the resonance frequency of the actuator chamber. In general, the maximum heating frequency that can be applied will be determined by the material properties of the piezoelectric element and the dimensions of the actuating chamber, as well as the specifics of the waveform, such as the slew rate and maximum voltage, that are achievable by the electronics.

According to one embodiment, the heating waveform comprises one or more ‘edges’ in the waveform and a slew rate of 10 to 200 V/μs.

According to the present method, it is possible to pole piezoelectric elements 24 at either wafer level or die level without requiring an external heating apparatus, since the existing circuitry, that will be included in the printhead, can be used to both heat the actuators by applying heating waveforms and to pole the piezoelectric elements by applying poling waveforms. In addition, it is possible to pole the piezoelectric elements 24 of an actuator die 50 once the die has been assembled into a printhead. Regarding the die level for example, with reference to FIG. 1, when the electrical trace 32a of the first electrode 28 is in electrical communication with a first electrical contact 35, whilst the electrical trace 32b of the second electrode 26 is in electrical communication with a second electrical contact 37, and the electrical contacts 35/37 are in electrical communication with a controller, the controller may be utilised to apply the heating waveform to the piezoelectric element of the actuators 22 in order to increase the temperature of the piezoelectric elements 24, and to apply the poling waveform to the piezoelectric elements 24 to pole them. Such a controller may be the controller used for controlling the printhead during normal printing operation.

Where a die is such that its part size is sufficiently small and thermal conductivity of its parts is good, heat is spread fast and evenly so that all piezoelectric elements of the die experience the same temperature.

The fluidic chamber substrate 2 may be manufactured from a silicon (Si) wafer of the order of 100 μm thick. Si is a good thermal conductor, and therefore provides a fast and even temperature distribution medium across the entire actuator die. It is possible that the membrane materials, which may comprise materials such as silicon nitride (Si₃N₄), silicon dioxide (SiO₂), aluminium oxide (Al₂O₃), titanium dioxide (TiO₂) or silicon carbide (SiC), may conduct heat less efficiently due to having lower thermal conductivity than Si such that heat is less efficiently transferred from the membrane to the piezoelectric element. However, the heating waveform parameters can be adjusted to compensate for these losses. Therefore, when a heating waveform is applied to only some of the piezoelectric elements of the actuators 22 of the die, there is an even temperature increase across the entire die. The entire actuator die is heated up.

Once the piezoelectric actuators 22 are assembled in an inkjet printhead, the temperature to which the actuators may be heated is limited by the temperature at which damage to the materials or assembly of the piezoelectric inkjet printhead occurs. In addition, the poling waveform which is to be applied is limited by the capabilities of the controller as well as the piezoelectric material.

A heating waveform can be optimised to meet the limitations imposed by the circumstances and the variation of the temperature of the die can be controlled by tuning f (frequency of AC component), A (DC component), B (AC component), SR (slew rate) and the number of actuators to which the heating waveform is applied. For example:
as the frequency of the heating waveform increases, the temperature at the actuator to which the heating waveform is applied, and thus the temperature at the actuator die, increases;
as the AC component (|B|) of the heating waveform increases, the temperature at the actuator to which the heating waveform is applied, and thus the temperature at the actuator die, increases;
as the DC component (|A|) of the heating waveform increases the temperature at the actuator to which the heating waveform is applied, and thus the temperature at the actuator die, decreases; when the DC component is 0V and the heating waveform is bipolar, for example, the heating efficiency is improved;
as the slew rate SR is increased (i.e. steeper change in voltage), the temperature at the actuator to which the heating waveform is applied, and thus the temperature at the actuator die, increases;
as the number of actuators to which the heating waveform is applied increases, the temperature at the actuator die increases.

The heating of the actuator die can be further optimised by choosing an appropriate length of time for the application of the heating waveform and/or by applying the heating waveform to an appropriate number of actuators. The number of actuators to which the heating waveform is applied may be increased or decreased during the heating process.

TABLE 1

| Active Actuators (%) | T (° C.) |
|---|---|
| 0 | 23.05 |
| 12.5 | 39.6 |
| 25 | 59 |
| 37.5 | 69 |
| 50 | 81 |
| 62.5 | 91 |
| 75 | 97.4 |
| 87.5 | 101.5 |
| 100 | 105.5 |

Table 1 shows experimental data that exemplify the temperature rise that can be obtained by applying a heating waveform to an increasing number of actuators in a die. In this example the heating waveform had the parameters f=100 kHz, A=17 V, B=17 V, SR=100 V/μs. The temperature of the die was measured through a resistive temperature detector (Pt RTD) which is embedded in the Si die. It is expected that the maximum temperature change obtainable is dependent on the initial piezoelectric material properties, specifically, the temperature rise will depend on the amount of hysteresis induced by the voltage signal.

The heating waveform may be applied to as many of the actuators of the actuator die as required in order to increase the temperature of the actuator die to the poling temperature within a required duration of time. According to another embodiment, the heating waveform may be applied to all of the actuators of the actuator die in order to increase the temperature of the actuator die to the poling temperature.

Once the poling temperature has been reached, a poling waveform is applied to the actuators of the actuator die in order to pole one or more of the piezoelectric elements. In one embodiment, the poling waveform may be provided in the form of a constant voltage (DC) signal (B=0, f=0), provided the DC amplitude of the waveform satisfies |A|>|E_{c}|, where E_{c} is the coercive field of the piezoelectric material used in the actuator. It is further preferred that the DC amplitude of the poling waveform satisfies |E_{c}|<|A|≤10|E_{c}|. In other words, the DC component of the poling waveform needs to be high enough to pole the piezoelectric elements of the actuators.

The poling waveform is applied to one or more of the actuators of the actuator die in order to pole the piezoelectric elements of those actuators, whilst, at the same time, a maintenance heating waveform may be applied to one or more of the actuators of the actuator die in order to maintain the poling temperature of the actuator die.

For example, an actuator die may comprise 1500 actuators whose piezoelectric elements all need to be poled. The heating waveform may be applied to all of the piezoelectric elements of the actuators of the actuator die in order to increase the temperature of the piezoelectric elements of the actuators on the die from a first temperature to the poling temperature. The first temperature may be, for example, room temperature. By applying the heating waveform to all of the piezoelectric elements of the actuators of the actuator die, the temperature of the actuator die is increased to the poling temperature as quickly as possible. However, as mentioned above, the heating waveform does not need to be applied to all of the piezoelectric elements of the actuators of the actuator die.

Once the poling temperature has been reached, a poling waveform is applied to a first set of the piezoelectric elements of the actuators of the actuator die (for example, 750) in order to pole the first set of piezoelectric elements, whilst a maintenance heating waveform may be applied to a second set of piezoelectric elements of the actuators of the actuator die (for example but not necessarily, the other 750 actuators) in order to maintain the poling temperature at the actuator die during poling. The poling waveform is applied to the first set of piezoelectric elements for a poling time period.

Once the poling time period expires, a holding poling waveform may be applied to the first set of piezoelectric elements, that have just been poled, and a further poling waveform is applied to the second set of piezoelectric elements of the actuator die in order to pole the second set of piezoelectric elements, at the poling temperature. A maintenance heating waveform may be applied, as required, to, for example, the first set of piezoelectric elements of the actuators of the actuator die in order to maintain the poling temperature at the actuator die during poling of the second set of piezoelectric elements. The holding poling waveform and the maintenance heating waveform may be applied to the first set of piezoelectric elements at the same time, if required. The maintenance heating waveform applied to maintain the poling temperature may be different from the heating waveform previously applied to reach the poling temperature, for example by adjusting one or more of the parameters in equation (2). Where a maintenance heating waveform is applied to those piezoelectric elements that have already been treated with the poling waveform at the poling temperature, such maintenance heating waveform preferably meets the condition that |A|>|E_{c}|, or more preferably still |E_{c}|<|A|≤10|E_{c}|, in order to not depole those piezoelectric elements. The holding poling waveform may be different from the poling waveform and preferably meets the condition that |A|>|E_{c}|. The further poling waveform which is applied to the second set of piezoelectric elements, at the poling temperature, may be the same as or different from the poling waveform applied to the first set of piezoelectric elements. The further poling waveform is applied to the second set of piezoelectric elements for a poling time period. The duration of the poling time period for which the further poling waveform is applied to the second set of piezoelectric elements may be the same as or different from the duration of the poling time period applied for which the poling waveform is applied to the first set of piezoelectric elements. When the further poling waveform which is applied to the second set of piezoelectric elements is different from the poling waveform which is applied to the first set of piezoelectric elements, then the duration of the poling time period for application of the further poling waveform is likely to be different from the duration of the poling time period for application of the poling waveform. A poling waveform is applied to all the piezoelectric elements of the actuators of the actuator die for a poling time period, whilst the actuator die is held at the poling temperature.

A maintenance heating waveform may not be required, if the actuator die has sufficient thermal properties such that the poling temperature is maintained during poling.

Although the above description refers to applying the heating waveform to the piezoelectric elements of the actuators of the actuator die in order to increase the temperature of the actuator die from the first temperature to the poling temperature, the heating waveform may be applied to the piezoelectric elements of the actuators irrespective of whether they are provided on a die, in order to increase the temperature of the actuators from the first temperature to the poling temperature.

Once the poling waveform has been applied to all of the piezoelectric elements of the actuators of the actuator die (or all actuator dies of the inkjet printhead) that need to be poled, the maintenance heating waveform, if applied, is removed and a holding poling waveform is applied to all of the piezoelectric elements of the actuator die, to which the poling waveform/further poling waveform was applied, to maintain the poling of the piezoelectric elements, during cooling of the actuator die. The holding poling waveform applied to the piezoelectric elements has no significant heating effect (it satisfies B=0, f=0, |E_{c}|≤|A|10|E_{c}|) and thus the actuator die cools down. The holding poling waveform is applied until the actuator die has cooled to a second temperature, such as room temperature. Once the actuator die has cooled to the second temperature, the holding poling waveform is removed. The holding poling waveform applied during cooling of the actuator die may be the same as or different from the holding poling waveform applied to the first set of piezoelectric elements during poling of the second set of piezoelectric elements.

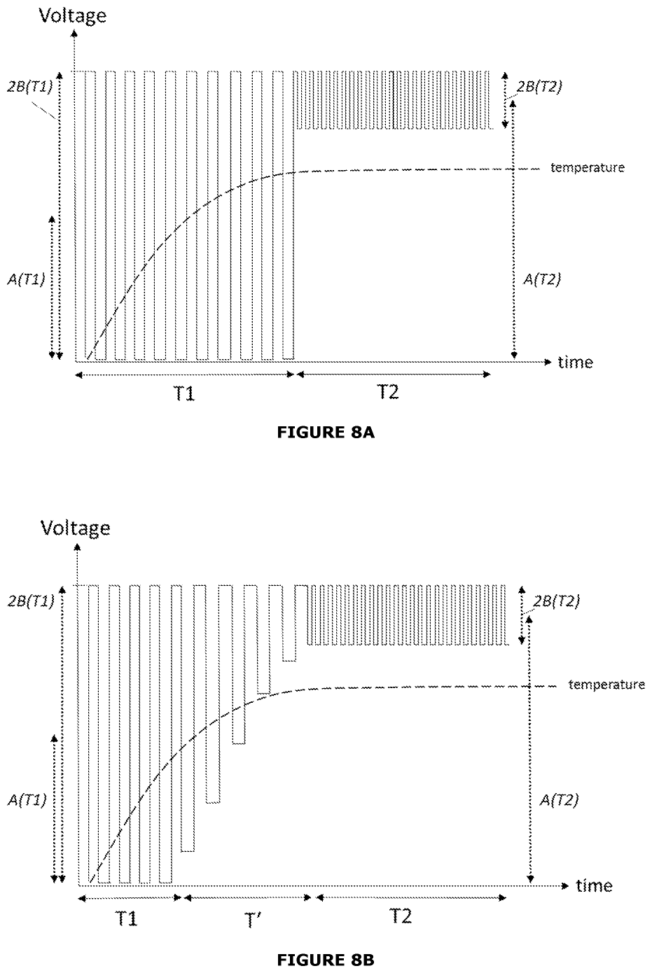

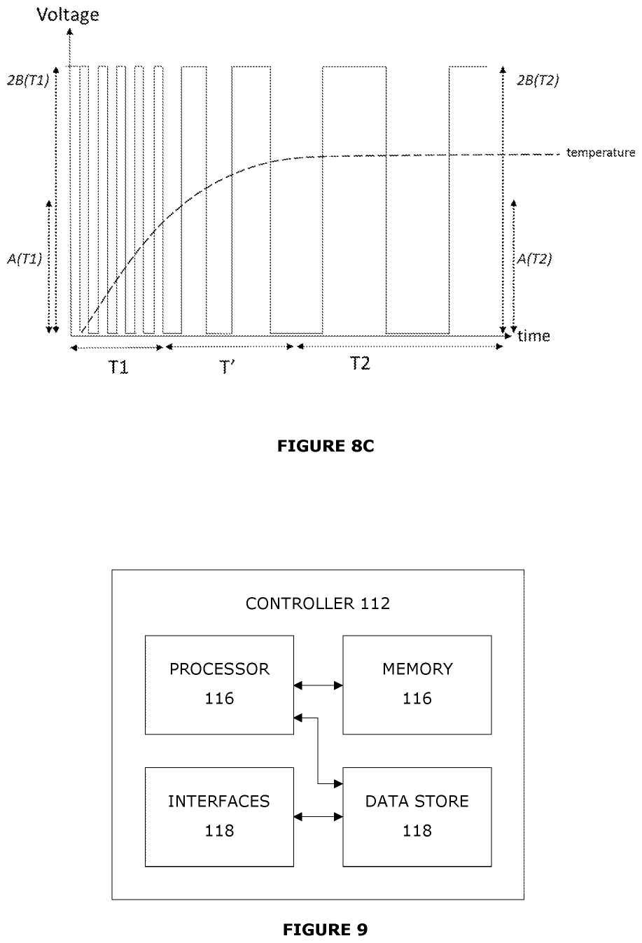

According to another embodiment, once the poling temperature has been reached, a poling and heating waveform may be applied to one or more of the actuators of the actuator die in order to pole the piezoelectric elements of those actuators, whilst maintaining the poling temperature of the actuator die. Poling and heating waveforms are discussed in detail below with reference to FIGS. 8A to 8C. However, a poling and heating waveforms satisfies |B|>0, f>0, |A|≥E_{c}|.

Once the poling and heating waveform has been applied to all of the piezoelectric elements of the actuators of the actuator die (or all actuator dies of the inkjet printhead) that need to be poled, a holding poling waveform is applied to all of the piezoelectric elements of the actuator die, to which the poling and heating waveform was applied, to maintain the poling of the piezoelectric elements, during cooling of the actuator die. The holding poling waveform applied to the piezoelectric elements has no significant heating effect (it satisfies B=0, f=0, |E_{c}|<|A|≤10|E_{c}|) and thus the actuator die cools down. The holding poling waveform is applied until the actuator die has cooled to a second temperature, such as room temperature. Once the actuator die has cooled to the second temperature, the holding poling waveform is removed.

A multi-stage cooling process may alternatively be used, for example to control a cooling down ramp rate. In this case, the first stage may involve applying a poling and heating waveform with a heating effect (|B|>0, f>0), less than that needed to maintain the poling temperature, so as to lower the temperature from the poling temperature, and preferably including a poling component |E_{c}|≤|A|10|E_{c}|. The second stage may involve the application of a holding poling waveform with no significant heating effect (B=0, f=0) until the second temperature is reached. The second stage may be omitted if the poling and heating waveform is applied until the second temperature is reached.

As stated above, all of the waveforms may be supplied from the controller to the upper electrode 28 and/or lower electrode 26 of the piezoelectric actuators 22. Consequently, the poling process described herein does not require an external heating element or external circuitry.

Alternatively, external circuitry may be used to supply the waveforms to the upper electrode 28 and/or lower electrode 26 of the piezoelectric actuators 22 of the actuator die. In either case, the poling process described herein does not require an external heating source.

Although the above description refers to a first set and a second set of actuators or piezoelectric elements, the actuators or piezoelectric elements may be divided into as many, or as few, sets as required, or may not be divided into sets at all, for example, when the poling and heating waveform is applied. In addition, the heating waveform may be applied to as many, or as few, of the piezoelectric elements of the actuators of the actuator die as required in order to increase the temperature of the actuator die from the first temperature to the poling temperature. The poling waveform may be applied to as many, or as few, of the piezoelectric elements of the actuators of the actuator die as required. The maintenance heating waveform may be applied to as many, or as few, of the piezoelectric elements of the actuators of the actuator die as required in order to maintain the temperature of the actuator die at the poling temperature. Alternatively, a maintenance heating waveform may not be applied, as required, based on the capability of the actuators die to maintain the poling temperature, for example, by being provided with thermal insulation means. The poling and heating waveform may also be applied to as many, or as few, of the piezoelectric elements of the actuators of the actuator die, as required to pole the piezoelectric elements and maintain the poling temperature of the die, or to control the cooling rate of the actuators or die. Alternatively, the poling and heating waveform may not be applied to any of the piezoelectric actuators during cooling of the actuators or die, and a holding poling waveform may be applied instead.

After poling all the piezoelectric elements that need to be poled, the temperature of the actuator die decreases from the poling temperature to a second temperature whilst a holding poling waveform is being applied, as described above. According to one embodiment, the first temperature may be the same temperature as the second temperature. However, the second temperature is not required to be the same temperature as the first temperature. For example, the second temperature may be 40° C., and the holding poling waveform may be applied until the temperature has decreased from the poling temperature to 40° C.

The heating waveform may be the same as or different from the maintenance heating waveform.

If one or more of the piezoelectric elements do not need to be poled, e.g. because it has been poled previously, then those one or more piezoelectric elements may require a holding poling waveform, preferably characterised by |A|≥|E_{c}|, to be applied to them for, at least, as long as the temperature is high enough that it may cause thermal depoling. This holding poling waveform may be the same as the poling waveform or the holding poling waveform applied during cooling, or it may be different from one or both of them.

In addition, the poling waveform applied to a first set of piezoelectric elements, whilst the poling temperature is being maintained, may be the same or different from a further poling waveform applied, either subsequently or at the same time, to a further set of piezoelectric elements. For example, |A| may be different. In addition, the poling waveform applied to a first set of piezoelectric elements, whilst the poling temperature is being maintained, may be applied for a different poling time period from a further poling waveform applied to a further set of piezoelectric elements.

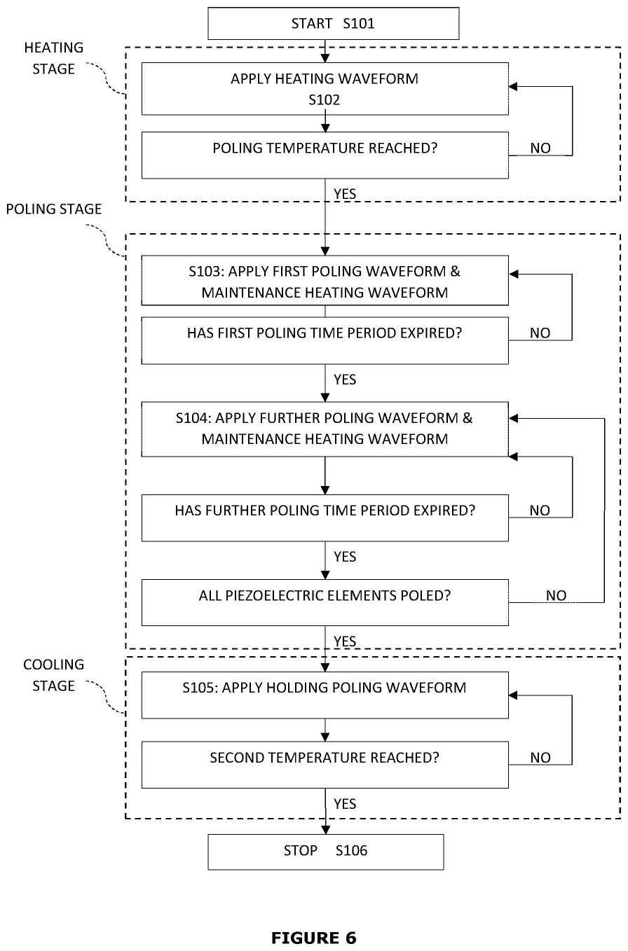

FIG. 6 illustrates a flow diagram of a process for poling the piezoelectric elements of a plurality of piezoelectric actuators. The process begins at step S101. At step S102 a heating waveform is applied to one or more piezoelectric elements from a plurality of piezoelectric actuators. The heating waveform may be applied to as many of the piezoelectric elements as required in order to increase the temperature of the actuators from a first temperature to the poling temperature. A holding poling waveform, characterised by |A|≥|E_{c}|, may be applied to all those piezoelectric elements from the plurality of piezoelectric elements that do not require to be poled, for, at least, as long as the piezoelectric elements are held at a temperature high enough that it may cause thermal depoling. Once the poling temperature has been reached, the process moves on to step S103.

At step S103 a poling waveform is applied to one or more piezoelectric elements, that may be the same as or different from the elements to which the heating waveform was applied at step S102, for a predetermined poling time period, whilst a maintenance heating waveform may optionally be applied, as required, to one or more piezoelectric elements to maintain the poling temperature at the actuator die. The maintenance heating waveform may include |A|≥|E_{c}|, for example this may be useful for elements that were already poled. When the actuator die has sufficient thermal properties such that the poling temperature is maintained during application of the poling waveform, then a maintenance heating waveform may not be required, and only the poling waveform is applied at step S103.

When the poling time period has expired, a holding poling waveform is applied to the one or more piezoelectric elements that have just been poled and, if not all the piezoelectric elements which require to be poled have been poled, the process moves on to step S104.

A poling waveform is applied to one or more piezoelectric elements whilst a maintenance heating waveform may optionally be applied to one or more other piezoelectric elements, such that the piezoelectric elements are poled in groups of one or more piezoelectric elements. Following poling of a first group of piezoelectric elements, the process moves onto step S104.

At step S104, for a predetermined further poling time period, a further poling waveform is applied to a further one or more piezoelectric elements of the plurality of piezoelectric elements of the actuators, which are different from the elements already poled (another group), whilst a further maintenance heating waveform, which may include |A|≥|E_{c}|, may optionally be applied, as required, to one or more piezoelectric elements to maintain the poling temperature at the actuator die. As stated above, when the actuator die has sufficient thermal properties such that the poling temperature is maintained during application of the poling waveform, then a further maintenance heating waveform may not be required, and only the further poling waveform is applied at step S104.

The piezoelectric elements to which a further maintenance heating waveform is applied at step S104 may or may not be the same as the piezoelectric elements to which the poling waveform and/or the maintenance heating waveform were previously applied at step S103.

The predetermined further poling time period applied at step S104 may be different from the poling time period applied at step S103. When the further poling time period has expired, a holding poling waveform is applied to the one or more piezoelectric elements that have just been poled and it is determined if all of the piezoelectric elements which require to be poled have been poled. When it is determined that not all of the piezoelectric elements which require to be poled have been poled, the process goes back to step S104, and another group of piezoelectric elements are poled. When it is determined that all of the piezoelectric elements which require to be poled have been poled, then the process moves on to step S105.

The poling temperature applied at step S103 may be different from the poling temperature applied at one or any of the further steps S104, and may depend on whether a maintenance heating waveform is being applied to some of the actuators, and if so, depending on whether the maintenance waveform is to achieve the same poling temperature as that experienced by previous piezoelectric elements of the plurality of piezoelectric elements.

At step S105, a holding poling waveform is applied to the piezoelectric elements which were poled in steps S103 and S104 or which did not need to be poled. The holding poling waveform may or may not be the same as the first or further poling waveforms, for example, the holding poling waveform may have a lower |A| value than the poling or further poling waveforms. Since there is no maintenance heating waveform applied at step S105, the actuators cool down from the poling temperature to a second temperature, which may or may not be the same as the first temperature. Once the actuators have cooled down to the second temperature, the process ends at step S106.

The poling time period required for a given poling temperature and poling field/waveform, can be determined via membrane displacement measurements using laser interferometry; or drops-in-flight investigation by measuring drop velocity for a given voltage, for a given piezoelectric element type (such as material, thickness). A balance will have to be struck between manufacturing time/printhead down time on one hand, requiring poling time to be as short as possible, and achieving better/more stable poling enhancement results achievable by a longer poling time on the other hand.

It may therefore be necessary to also measure performance stability for different poling conditions to ensure that the poling state achieved remains stable over an acceptable time period of printhead operation.

A multi-stage cooling process may also be used for step S105 where it is desirable to control the cooling down ramp rate. For example, a first stage of cooling at step S105 may involve a holding poling and heating waveform with a heating effect (B>0, f>0) less than that needed to maintain the poling temperature, where parameters are controlled to lower the temperature in a controlled way, e.g. more slowly than through cooling by the actuator die environment, to an intermediate temperature. For example, one or more of the parameters f, A, B, or SR of the holding poling and heating waveform may be varied with time for example to control cooling over time. Once the intermediate temperature has been reached, a second cooling stage starts. This might involve the application of a holding poling waveform, with no significant heating effect (B=0, f=0), until the second temperature is reached. It will be understood that the second cooling stage may be omitted where the first cooling stage is prolonged until the second temperature is reached.

The holding poling waveform used in a single stage or multistage cooling process may be different for different groups of piezoelectric elements, depending on their poling condition. For example, some groups may be held at a different holding poling waveform because they were the final groups to be poled while other groups supplied the maintenance heating waveform(s). The holding poling waveform may be different in the A component, or in the B component it may supply, so that some groups cool faster than others.

The heating waveform which is applied to the piezoelectric elements may not be the same waveform throughout the process. During the initial heating step (step S102 in FIG. 6), when the temperature at the actuator die increases from a first temperature, such as room temperature, to the poling temperature, the frequency and/or the voltage (AC amplitude, B) of the heating waveform may be higher in order to rapidly increase the temperature of the actuator die. In addition, it may be preferable to apply the heating waveform to all, or substantially all, of the piezoelectric elements during the initial heating step (step 102 in FIG. 6), in order to rapidly increase the temperature of the actuators to the poling temperature, as quickly as possible. During the poling steps (steps S103 to S104 in FIG. 6), when the temperature is maintained at the poling temperature, the frequency and/or the voltage (AC amplitude, B) of the heating waveform may be lower than at the initial heating step.

In addition, the mode by which heating is achieved (change in frequency/slew rate/voltage/number of actuators) may be altered during heating in order to more finely control the temperature.

As is known in the art, internal temperature sensors, such as resistive elements, provided as part of the individual actuators and/or the actuator die and/or inkjet printhead may be utilised to monitor the temperature of each actuator and/or die. The temperature measurement may be used by the controller or the external circuitry in order to determine whether the poling temperature has been reached and in order to determine whether the poling temperature is being maintained, e.g. at the actuator die, during the application of the poling waveform. The temperature measurement may also be used by the controller or the external circuitry in order to determine whether the actuator die has cooled down to the intermediate or second temperature.

Such temperature measurements may also be used during the heating step, from the first temperature to the poling temperature, to apply a multi-stage heating process. For example, a two-stage heating process may involve determining a temperature intermediate of the starting first temperature and the poling temperature at which heating is to be switched from a first heating waveform to a second heating waveform. This may be desirable to prevent, for example, overshooting of temperature once the temperature nears the poling temperature. According to one embodiment of a multi-stage heating process, during a first heating stage, a first heating waveform which generates a significant amount of heating, e.g. by using a high frequency and/or amplitude, may be applied. When the temperature reaches a predetermined near-poling temperature (i.e. a predetermined intermediate temperature), a second heating waveform, e.g. a waveform having a different frequency/amplitude and/or slew rate from the first heating waveform, may be applied to generate a lower heating ramp rate during a second heating stage. This ensures that the poling temperature is approached more slowly during the second heating stage and the poling temperature is not significantly overshot.

The method described above, with reference to FIG. 6, poles a first group of piezoelectric elements (one or more piezoelectric elements) whilst at the same time applying a maintenance heating waveform, if required, to a second group of piezoelectric elements (different to the first group) to maintain the poling temperature of the actuators. However, as discussed above, it is also possible to pole a first group of piezoelectric elements (one or more piezoelectric elements, all the piezoelectric elements etc.) whilst at the same time applying the maintenance heating waveform to the same first group of piezoelectric elements (one or more piezoelectric elements, all the piezoelectric elements etc.) to maintain the poling temperature of the actuators. This is achieved by applying the poling and heating waveform, tuned so as to have both a DC component (|A|≥|E_{c}|) and a significantly high AC component (|B|≥0). Combinations of the above two options are also possible.

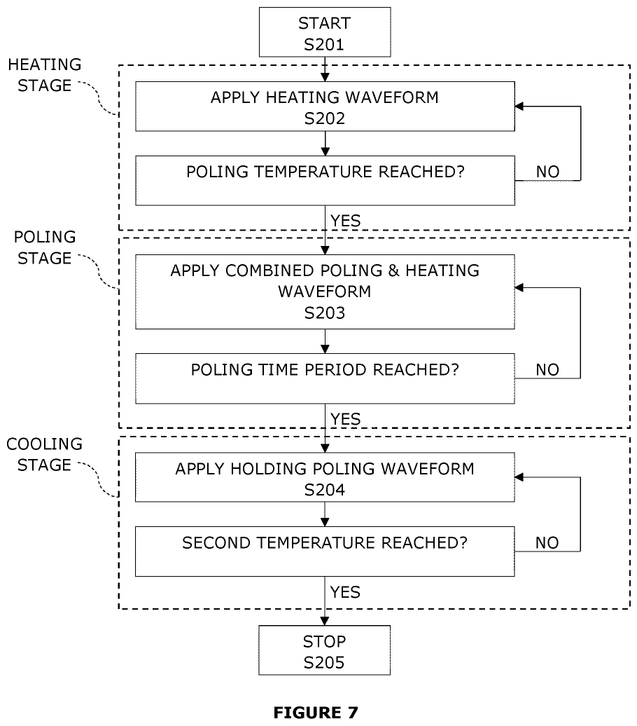

FIG. 7 illustrates a flow diagram of a process for poling the piezoelectric elements of a plurality of piezoelectric actuators. The process begins at step S201. At step S202, a heating waveform is applied to as many of the piezoelectric elements as required in order to increase the temperature of the actuators from a first temperature to the poling temperature within a predetermined amount of time. In this waveform, the DC component A might be 0. A holding poling waveform, characterised by |A|≥|E_{c}|, may be applied to all those piezoelectric elements that do not require to be poled, for, at least, as long as the piezoelectric elements are held at a temperature high enough that it may cause thermal depoling. Once the poling temperature has been reached, the process moves on to step S203.

At step S203, for a predetermined poling time period, a poling and heating waveform is applied to all of, or some of, the piezoelectric elements which require to be poled, where the poling and heating waveform provides for poling as well as maintaining the poling temperature of the actuators (by tuning one or more of the AC amplitude B, frequency f, slew rate SR, etc.). In other words, a poling and heating waveform is applied having |A|≥|E_{c}| (poling component), |B|>0 and f≠0 (heating component). The heating component may be applied to all of the piezoelectric elements which require to be poled, or as many of the piezoelectric elements as required in order to maintain the temperature of the actuators at the poling temperature.

It may be desirable to ensure that each actuator experiences the same net heating/poling conditions, for example where the performance of the whole printhead die or printhead is to be recovered. There may, on the other hand, be cases where individual actuators require to be poled to adjust their performance to that of the surrounding actuators, for example to correct for original actuator non-uniformity in performance. In such cases the net heating/poling conditions may be different.

Once the poling time period has expired, the process moves on to step S204. An additional step may be included, similar to the “ALL PIEZOELECTRIC ELEMENTS POLED?” step of FIG. 6, which is not illustrated in FIG. 7, prior to step S204. The additional step may perform a check, following expiry of the poling time period, as to whether all of the piezoelectric elements which are required to be poled, have been poled. When there are piezoelectric elements which require to be poled, which have not been poled, then the process does not move onto step S204, instead, a poling and heating waveform is applied to the piezoelectric elements which still require to be poled, for the poling time period.

At step S204, the waveform is changed to a holding poling waveform that is applied to all of the piezoelectric elements which were poled at step S203. The holding poling waveform may or may not have the same poling properties as the poling and heating waveform, for example, the holding poling waveform may have a lower |A| component than the poling and heating waveform of step S203. Since heating is no longer being applied to the piezoelectric elements, the actuators cool down from the poling temperature to a second temperature. The second temperature may or may not be the same as the first temperature.

Once the actuators have cooled down to the second temperature, the process ends at step S205 and the holding poling waveform is removed.

As before, a multi-stage cooling process may also be used to control the cooling ramp rate, in a similar fashion as described for step S105 of FIG. 6, such that step S204 utilises a holding poling and heating waveform, at least initially, to alter the rate of cooling of the poled actuators.

It will be understood that, generally, poling of a piezoelectric element of a given material and thickness may be affected by the combination of the poling conditions such as the poling temperature, the poling field or voltage applied to the piezoelectric element, and the poling time period. For example, a similar level of poling may be achieved over the same poling time period for a given combination of medium poling temperature and high poling field compared to a high poling temperature and medium poling field. As a result, in practice, the applied heating waveform, when it has a DC component |A|>|E_{c}|, will begin to pole the piezoelectric elements starting from the stage where the actuator die is at the first temperature. The rate of poling will increase as the temperature increases and/or the field across the element increases. It is therefore possible to design an efficient process that balances the duration of the poling process against harshness of conditions with respect to the materials of the actuator die and, as potentially in the case of the assembled printhead, the ink within the die.

In addition, a combined process where a waveform with both A and B (and f)≠0 may be used where the waveform is gradually adjusted in one or more of its parameters to turn from a predominantly heating waveform into a predominantly poling waveform.

FIGS. 8A, 8B and 8C illustrate schematically poling and heating waveforms for maintaining temperature whilst poling.

FIG. 8A shows a waveform which, during the time period T1, is optimised for heating output by having a larger AC component B, and a smaller DC component A. When the poling temperature is reached, at the end of T1, and the time period T2 starts, the AC component is decreased to maintain the temperature, and the DC component is increased to effectively pole the piezoelectric elements. The dotted line in FIG. 8A illustrates the variation of temperature as the waveform portions are applied over time periods T1 and T2.

In this example, during the time period T2, the frequency of the combined waveform is shown to have increased to maintain the poling temperature. According to FIG. 8A, the change in A and B components is discrete, and applied at a temperature near or at the poling temperature. Essentially, the second waveform portion over time period T2 has both an oscillating element, B, as well as a DC element, A, by being offset from 0V. The effect is one of poling and maintenance heating applied to the same piezoelectric element(s).

Improvements over the approach in FIG. 8A are shown in FIGS. 8B and 8C. In FIGS. 8B and 8C, the waveform parameters are varied gradually to better control the temperature evolution as the temperature nears the poling temperature, and to avoid overshooting of the temperature by gradually decreasing the heating effect of the waveform.

In FIG. 8B, there is a gradual transition over a transition time period T′ from the first non-varying waveform portion applied over time period T1 (rapid heating), to the second non-varying waveform portion applied over time period T2 once the poling temperature is reached. During the transition time period T′, the DC component A and the AC component B are shown to vary in this example. In alternative examples, the frequency during time period T1 may also gradually decrease. The frequency may initially be higher than that of the waveform applied during the time period T2 and may be gradually reduced to the frequency of the waveform applied during the time period T2.

In FIG. 8C, the DC component A and the AC component B are maintained constant throughout the process, however the frequency is gradually decreased during time period T′ to gradually reduce the heating effect from rapid heating to maintenance heating. Once the poling temperature is reached from the start of the time period T2, the frequency becomes constant but is a lower frequency compared to the initial frequency applied during time period T1 for the initial temperature ramp. In FIG. 8C, the time during which the piezoelectric elements are not under electric field is kept short to counteract thermal depoling. The skilled person will appreciate that the value of other parameters in Equation (2) may be tailored to achieve the desired effect of poling and heating.

In the above description, the term ‘heating waveform’ (including maintenance heating waveform, etc.) is used to describe waveforms for which the predominant function is heating, and the term ‘poling waveform’ (including holding poling waveform, etc.) is used to describe waveforms for which the predominant function is poling.

Meanwhile, the term ‘poling and heating waveform’ (including holding poling and heating waveform and poling and maintenance heating waveform, etc.) is used to describe waveforms where there may not be a clear distinction whether a portion or all of a waveform has a function for which heating or poling are predominant. Furthermore, in some of the cases described, the parameters of the waveform may be adjusted gradually to turn a waveform that predominantly heats initially into one that also poles, and may predominantly pole and heat with less predominance in a later stage. The processes described with reference to FIGS. 8A to 8C may be considered as having a combined time period over which all stages of the process are applied to the piezoelectric elements, regardless of whether the combined time period can be broken up into distinct heating/poling/maintenance/holding poling time periods or not.

The waveforms described may, in addition, apply small pulses, e.g. over the top of a DC portion to pole the piezoelectric element, to the piezoelectric elements so as to perturb the meniscus of the ink in the nozzle at specified times without ejecting a droplet. This may be necessary to avoid the ink from becoming too viscous inside the nozzle during poling. Other non-ejecting or ejecting signals as known in the art may be applied during the process as necessary but are not described in detail here.

It will further be appreciated that in some cases maintenance heating waveforms may not need to be applied since the plurality of actuators is provided with insulation means that insulate it from the external environment, or where the actuator is in its dry conditions so that ink cannot dissipate any heat. In those cases the V(T) curve during the time period T2, in the examples shown in FIGS. 8A, B and C, would be represented by a straight horizontal line at V=A(T2).

The processes described above may be used to pole a plurality of piezoelectric elements of an actuator die in an inkjet printhead. Furthermore, the processes described above may be used to re-pole the piezoelectric elements in an actuator die in an inkjet printhead following use, which will be referred to herein as the “recovery poling process”. As is known in the art, over time and with use, the polarisation of piezoelectric elements can reduce. Therefore, the actuator performance degrades during use.

The above processes may be used to restore performance to inkjet printheads by re-poling the actuators in situ, whilst ink is in the cavities. The actuators may still degrade over time following the recovery poling process, and may be re-poled more than once.

Following assembly and use, the actuator dies 50 will have ink in the fluidic chambers 10, fluidic channels 12/15, fluidic inlet/outlet ports 13/16, fluidic channels 14 and nozzles 18. The ink in the actuator dies 50 must not overheat during the recovery poling process. Therefore, during the recovery poling process, different parameters (poling temperature/poling electric field strength/poling time period) may be used, when compared to the poling process when used with empty actuator dies 50. This is because, following assembly of an inkjet printhead, the poling temperature is likely to be required to be a lower temperature, since the temperature is restricted by the degradation temperature of the ink in the cavities, at which the ink, or any ink component degrades, and the melting/failure temperature of the adhesives used etc. A reduction in the poling temperature will require changes to the poling waveform/poling time period.

For example, the poling process may have a poling temperature of between 120° C. to 150° C., whereas the recovery poling process may have a poling temperature of approximately 70° C. For example, aqueous inks may withstand a higher poling temperature compared to UV curable inks.

Notwithstanding the above limitations, the poling and heating process can be optimised to the particular circumstances by tuning the parameters of Equation (2) as discussed above.

In addition, although not mandatory, it is preferred that the DC component A in the waveform used in the recovery poling process should be lower than the voltage required for jetting the ink from the nozzle 18. Although it is acceptable for the meniscus in the nozzle to be perturbed, droplets of ink should not be ejected from the nozzle as a result of the recovery poling process, unless an ejection command is issued. During the recovery process, ink may be ejected in a controlled manner at specified times from the nozzles as a result of applying a droplet ejection signal. The periodic ejection of ink during the recovery process helps to prevent clogging and to maintain a reliable nozzle. However, the ejection of ink should not result in significant heat loss from the actuator die. Therefore, a balance should be reached between the requirement to clear the nozzles at specified times whilst maintaining the poling temperature at the actuator die. For example, a droplet ejection signal may be applied once every 30 seconds, once every 5 seconds etc. The time elapsed between such periodic droplet ejection signals may depend on the type of ink used in inkjet printhead and the poling conditions.

In addition, a different poling temperature/poling waveform/poling and heating waveform/poling time period may be applied to different actuators of the inkjet printhead, for example, when different ink is provided in different rows/groups of the actuator die, for example where different inks require different ejection conditions that reduce the performance of the piezoelectric elements of those rows/groups differently compared to others, or where the actuators in different actuator die of the same printhead require recovery poling to balance performance. The different poling waveform/poling and heating waveform may be applied to different piezoelectric elements of the actuators at the same, or at different times. In an actuator die design that provides a temperature break between rows/groups, for example in the form of a low temperature coefficient separation such as a groove filled with air or a poor temperature conductor, it may be possible to provide different heating/cooling conditions to the different rows/groups.

Generally, it may be desirable that all piezoelectric elements of the actuator die, or of the printhead, receive a poling waveform for a poling time period at some point in the process. Different groups of piezoelectric elements may receive different poling conditions, depending on their respective performances, for example. However, not all of the groups are required to receive a heating waveform, as long as enough of the actuators receive the heating waveform in order to reach and maintain the poling temperature during poling.

FIG. 9 illustrates schematically a controller 112 with which electrical contacts 35/37 are in electrical communication. The controller 112 comprises at least one processor 116 coupled to at least one memory 120. The memory 120 may comprise program memory storing computer program code to implement the processes described herein, and working memory. The program memory of memory 120 may be used for buffering data (for example, image data received by the controller 112) while executing the computer program code. The processor 116 may comprise processing logic to process data (for example, image data, programs, instructions received from a user, etc.) and feedback from the printhead or actuator die, and generate output signals in response to the processing. Specifically, the processor may receive feedback from one or more temperature sensors mounted to the actuator die, or temperature sensors provided per piezoelectric element. Most suitably, temperature is continuously monitored and fed back to the processor. The processor further uses information provided via the user interface or stored in the memory 120 as to heating and poling conditions, maximum temperatures acceptable to the actuator die and/or printhead, maximum poling voltage, time periods relevant to the poling process, and performance values of the actuators to assess whether, in the case of an assembled printhead, recovery poling is required. The processor uses the data available to, for example,
initiate a heating and poling process by generating output signals to control the waveform(s) applied to one or more piezoelectric elements of an actuator die or printhead;
adjust the waveform from e.g. a heating waveform to a poling waveform once the poling temperature has been reached;
adjust the maintenance heating waveform in response to data received from the temperature sensor(s) of the actuator die or piezoelectric elements;
time the poling time period to control the cooling process once the poling time period has expired;
adjust, based on feedback such as temperature, the waveform properties and/or number of actuators, such as to, for example, reduce a rate of heating;
store information on which piezoelectric elements have been poled and which have not, and assess the heating/poling history for each piezoelectric element.

The waveform may be supplied from a circuit internal to or in communication with the processor 116, and may be a common waveform to groups of actuators of an actuator die, or to all actuators of the actuator die. Such a common waveform may be adjusted per actuator or per group of actuators in response to a drive signal generated in response to e.g. image data or heating/poling commands by an intermediate circuit located at or near the printhead. Such adjustment of the common waveform may be altering the DC and/or AC components of the waveform (A and/or B) and/or slew rate, for example, per group of actuators, so as to alter the heating rate or poling conditions.

The controller may further receive performance data it may use to trigger a recovery poling procedure. The performance data may be supplied by the user, such as drop placement data (from a print test on a print media) or drop velocity data of the printhead actuators as based on performance testing, or received from the printhead, such as a count of actuations per actuator. If such data is determined by the controller to be too far away from a predetermined threshold, or varies by a value defined as being too high from an average value to provide a uniform printhead or die performance, the controller may trigger a recovery poling procedure based on the number of actuators or dies that require to be repoled.

The controller 112 comprises interfaces 118, such as a conventional computer screen, keyboard, and mouse, and/or other interfaces such as a network interface and software interfaces (e.g. a data store interface). The interfaces 120 preferably comprise a communication interface to receive an image or image data for printing, which may be processed image data. The controller 112 comprises a data store 122 configured to store, for example, one or more lookup tables used to configure the nozzles 18. Data store 122 may be coupled to the communication interface of interfaces 118 to, for example, receive data. The data store 122 may be configured to communicate with the at least one processor 116.

As will be appreciated by one skilled in the art, the present techniques may be embodied as a system, method or computer program product. Accordingly, the present techniques may take the form of an entirely hardware embodiment, an entirely software embodiment, or an embodiment combining software and hardware.

Furthermore, the present techniques may take the form of a computer program product embodied in a computer readable medium having computer readable program code embodied thereon. The computer readable medium may be a computer readable signal medium or a computer readable storage medium. A computer readable medium may be, for example, but is not limited to, an electronic, magnetic, optical, electromagnetic, infrared, or semiconductor system, apparatus, or device, or any suitable combination of the foregoing.

Computer program code for carrying out operations of the present techniques may be written in any combination of one or more programming languages, including object oriented programming languages and conventional procedural programming languages.

It will also be clear to one of skill in the art that all or part of a logical method according to the preferred embodiments of the present techniques may suitably be embodied in a logic apparatus comprising logic elements to perform the steps of the method, and that such logic elements may comprise components such as logic gates in, for example a programmable logic array or application-specific integrated circuit. Such a logic arrangement may further be embodied in enabling elements for temporarily or permanently establishing logic structures in such an array or circuit using, for example, a virtual hardware descriptor language, which may be stored and transmitted using fixed or transmittable carrier media.

In one alternative, an embodiment of the present techniques may be realized in the form of a computer implemented method of deploying a service comprising steps of deploying computer program code operable to, when deployed into a computer infrastructure or network and executed thereon, cause said computer system or network to perform all the steps of the method.

In a further alternative, the preferred embodiment of the present techniques may be realized in the form of a data carrier having functional data thereon, said functional data comprising functional computer data structures to, when loaded into a computer system or network and operated upon thereby, enable said computer system to perform all the steps of the method.

It will also be understood that whilst various concepts are described above with reference to a piezoelectric inkjet printhead, such concepts are not limited to inkjet printheads, but may be applied more broadly in printheads, or more broadly still in droplet deposition heads, for any suitable application. Droplet deposition heads suitable for such alternative applications may be generally similar in construction to printheads, with some adaptations made to handle the specific fluid in question. An example may be a droplet deposition head for dosing of biological materials. The preceding description should therefore be understood as providing non-limiting examples of applications in which such a droplet deposition head utilising piezoelectric elements may be used.

A variety of fluids may be deposited by a droplet deposition head. For instance, a droplet deposition head may eject droplets of ink that may travel to a sheet of paper or card, or to other receiving media, such as ceramic tiling or shaped articles (e.g. cans, bottles etc.), to form an image, where the droplet deposition head may be an inkjet printhead or, more particularly, a drop-on-demand inkjet printhead. In such heads, the pattern of droplets ejected varies in dependence upon the input data provided to the head.

Alternatively, droplets of fluid may be used to build structures, for example electrically active fluids may be deposited onto receiving media such as a circuit board so as to enable prototyping of electrical devices, or polymer containing fluids or molten polymer may be deposited in successive layers so as to produce a 3D printed object.

In still other applications, droplet deposition heads might be adapted to deposit droplets of solution containing biological or chemical material onto a receiving medium such as a microarray.

Droplet deposition heads suitable for such alternative fluids may be generally similar in construction to printheads, with some adaptations made to handle the specific fluid in question.

It will be clear to one skilled in the art that many improvements and modifications can be made to the foregoing exemplary embodiments without departing from the scope of the present techniques.

As will be appreciated from the foregoing specification, techniques are described providing a method for poling piezoelectric elements of a plurality of piezoelectric actuators.

In embodiments, the holding poling waveform comprises a holding poling and heating waveform, and wherein the holding poling and heating waveform comprises a heating effect less than that needed to maintain the poling temperature.

In embodiments, the holding poling waveform comprises a first holding poling and heating waveform and a second holding poling waveform, and wherein the first holding poling and heating waveform comprises a heating effect less than that needed to maintain the poling temperature. The method further comprises: applying the first holding poling and heating waveform until the temperature of the plurality of piezoelectric actuators has decreased from the poling temperature to an intermediate temperature, and applying the second holding poling waveform until the temperature of the plurality of piezoelectric actuators has decreased from the intermediate temperature to the second temperature.

In embodiments, the method further comprises: applying, during the poling time period and/or during the application of the holding poling waveform, a further holding poling waveform to one or more of the piezoelectric elements, to which the poling waveform is not applied, to prevent thermal depoling.

In embodiments, the method further comprises: applying a maintenance heating waveform to one or more of the piezoelectric elements, different from the one or more piezoelectric elements to which the poling waveform is being applied, to maintain the poling temperature at the plurality of piezoelectric actuators during the poling time period.

In embodiments, the method further comprises: after expiry of the poling time period, applying a further poling waveform to one or more of the piezoelectric elements to which the poling waveform has not been applied, for a further poling time period; and after expiry of the further poling time period, applying the holding poling waveform to the one or more piezoelectric elements to which the further poling waveform was applied until the temperature of the plurality of piezoelectric actuators has decreased from the poling temperature to a second temperature.

In embodiments, the method further comprises: applying a further maintenance heating waveform to one or more of the piezoelectric elements, different from the one or more piezoelectric elements to which the further poling waveform is being applied, to maintain the poling temperature at the plurality of piezoelectric actuators during the further poling time period.

In embodiments, the method further comprises: applying, during the further poling time period and/or during the application of the holding poling waveform, a further holding poling waveform to one or more of the piezoelectric elements to which the further poling waveform is not applied to prevent thermal depoling.

In embodiments, the poling waveform and the further poling waveform are the same.

In embodiments, the poling time period and the further poling time period are the same.

In embodiments, the poling waveform comprises a poling and heating waveform, to pole the one or more piezoelectric elements and to maintain the poling temperature at the plurality of piezoelectric actuators during the poling time period.

In embodiments, the poling waveform is applied to the one or more piezoelectric elements to which the heating waveform was applied.

In embodiments, the method further comprises: applying a second poling and heating waveform to one or more of the piezoelectric elements different from the one or more piezoelectric elements to which the poling and heating waveform is applied, wherein the second poling and heating waveform is different from the poling and heating waveform.

In embodiments, the second poling and heating waveform is applied for a second poling time period, different from the poling time period.

In embodiments, the waveforms are expressed by the equation:

V(t)=f(t,f,A,B,SR)

wherein:
V=voltage;
t=time over which the waveform is applied;
f=frequency of a cycle of the waveform;
SR=slew rate;
A=DC component of the time varying voltage waveform; and
B=AC component of the time varying voltage waveform
and wherein the parameters are adjusted during the process according to the intended function of the waveform.

In embodiments, when the waveform has a heating effect, one or more of the parameters f, A, B, or SR of the waveform vary with time.

In embodiments, one or more of the parameters f, A, B, or SR of the holding poling waveform or the holding poling and heating waveform vary with time.

In embodiments, A and/or B vary with time.

In embodiments, f varies with time so as to alter the heating effect over time.

In embodiments, the plurality of piezoelectric actuators form an actuator die assembled in an inkjet printhead during poling.

In embodiments, a fluid is present in the actuator die during poling.

In embodiments, the poling temperature is lower than the degradation temperature of the fluid.

In embodiments, a modulus of A of the waveforms is lower than a voltage required to eject a droplet of ink from a nozzle of the actuator die.

In embodiments, the method further comprises: applying a droplet ejection signal to eject a droplet of ink from the nozzle, at specified times, during poling.

In embodiments, the inkjet printhead comprises a controller, and wherein the controller applies the waveforms to the piezoelectric elements.

1. A method for poling piezoelectric elements of two or more piezoelectric actuators, the method comprising:
applying a heating waveform to one or more of the piezoelectric elements to increase the temperature of the piezoelectric actuators from a first temperature to a poling temperature;
applying a poling waveform to one or more of the piezoelectric elements when the poling temperature has been reached, for a poling time period, to pole the one or more piezoelectric elements; and
after expiry of the poling time period, applying a holding poling waveform to the one or more piezoelectric elements to which the poling waveform was applied until the temperature of the piezoelectric actuators has decreased from the poling temperature to a second temperature.

2. The method of claim 1, wherein the holding poling waveform comprises a holding poling and heating waveform, and wherein the holding poling and heating waveform comprises a heating effect less than that needed to maintain the poling temperature.

3. The method of claim 1, wherein the holding poling waveform comprises a first holding poling and heating waveform and a second holding poling waveform, and wherein the first holding poling and heating waveform comprises a heating effect less than that needed to maintain the poling temperature, the method further comprising:
applying the first holding poling and heating waveform until the temperature of the piezoelectric actuators has decreased from the poling temperature to an intermediate temperature, and
applying the second holding poling waveform until the temperature of the piezoelectric actuators has decreased from the intermediate temperature to the second temperature.

4. The method of claim 1, further comprising:
applying, during the poling time period and/or during the application of the holding poling waveform, a further holding poling waveform to one or more of the piezoelectric elements, to which the poling waveform is not applied, to prevent thermal depoling.

5. The method of claim 1, further comprising:
applying a maintenance heating waveform to one or more of the piezoelectric elements, different from the one or more piezoelectric elements to which the poling waveform is being applied, to maintain the poling temperature at the piezoelectric actuators during the poling time period.

6. The method of any one of claim 1, further comprising:
after expiry of the poling time period, applying a further poling waveform to one or more of the piezoelectric elements to which the poling waveform has not been applied, for a further poling time period; and
after expiry of the further poling time period, applying the holding poling waveform to the one or more piezoelectric elements to which the further poling waveform was applied until the temperature of the piezoelectric actuators has decreased from the poling temperature to a second temperature.

7. The method of claim 6, further comprising:
applying a further maintenance heating waveform to one or more of the piezoelectric elements, different from the one or more piezoelectric elements to which the further poling waveform is being applied, to maintain the poling temperature at the piezoelectric actuators during the further poling time period.

8. The method of claim 6, further comprising:
applying, during the further poling time period and/or during the application of the holding poling waveform, a further holding poling waveform to one or more of the piezoelectric elements to which the further poling waveform is not applied to prevent thermal depoling.

9. (canceled)

10. (canceled)

11. The method of claim 1, wherein the poling waveform comprises a poling and heating waveform, to pole the one or more piezoelectric elements and to maintain the poling temperature at the piezoelectric actuators during the poling time period.

12. The method of claim 1, wherein the poling waveform is applied to the one or more piezoelectric elements to which the heating waveform was applied.

13. The method of claim 11, further comprising:
applying a second poling and heating waveform to one or more of the piezoelectric elements different from the one or more piezoelectric elements to which the poling and heating waveform is applied, wherein the second poling and heating waveform is different from the poling and heating waveform.

14. The method of claim 13, wherein the second poling and heating waveform is applied for a second poling time period, different from the poling time period.

15. The method of claim 1, wherein the waveforms are expressed by the equation:
V(t)=f(t,f,A,B,SR)
wherein:
V=voltage;
t=time over which the waveform is applied;
f=frequency of a cycle of the waveform;
SR=slew rate;
A=DC component of the time varying voltage waveform; and
B=AC component of the time varying voltage waveform
and wherein the parameters are adjusted during the process according to the intended function of the waveform.

16. The method of claim 15, wherein when the waveform has a heating effect, one or more of the parameters f, A, B, or SR of the waveform vary with time.

17. The method of claim 15, wherein one or more of the parameters f, A, B, or SR of the holding poling waveform or the holding poling and heating waveform vary with time.

18. The method of claim 16, wherein A and/or B vary with time.

19. The method of claim 15, wherein f varies with time so as to alter the heating effect over time.

20. The method of claim 1, wherein the piezoelectric actuators form an actuator die assembled in an inkjet printhead during poling.

21. The method of claim 20, wherein a fluid is present in the actuator die during poling.

22.-25. (canceled)

26. A controller for an inkjet printhead, wherein the printhead comprises two or more piezoelectric actuators, each actuator having piezoelectric elements, and wherein in order to pole one or more of the piezoelectric elements of the piezoelectric actuators, the controller is configured to carry out the steps of:
applying a heating waveform to one or more of the piezoelectric elements to increase the temperature of the piezoelectric actuators from a first temperature to a poling temperature;
applying a poling waveform to one or more of the piezoelectric elements when the poling temperature has been reached, for a poling time period, to pole the one or more piezoelectric elements; and
after expiry of the poling time period, applying a holding poling waveform to the one or more piezoelectric elements to which the poling waveform was applied until the temperature of the piezoelectric actuators has decreased from the poling temperature to a second temperature.
